(19) United States
(12) Patent Application Publication
(10) Pub. No.: US 2022/0026603 A1
(43) Pub. Date: Jan. 27, 2022

(54) METHOD FOR DEPOSITION OF DEPTH-VARYING REFRACTIVE INDEX FILMS

(71) Applicant: Applied Materials, Inc., Santa Clara, CA (US)

(72) Inventors: Andrew CEBALLOS, Santa Clara, CA (US); Ludovic GODET, Sunnyvale, CA (US); Karl J. ARMSTRONG, Sunnyvale, CA (US); Rami HOURANI, Santa Clara, CA (US)

(21) Appl. No.: 17/371,441

(22) Filed: Jul. 9, 2021

Related U.S. Application Data
(60) Provisional application No. 63/055,160, filed on Jul. 22, 2020.

(51) Int. Cl. G02B 1/115; C23C 16/40; C23C 14/08

(52) U.S. Cl. CPC G02B 1/115; C23C 14/083; C23C 16/405; C23C 16/401

(57) ABSTRACT

Embodiments of the present disclosure relate to optical device films and methods of forming optical device films. Specifically, embodiments described herein provide for an optical device film having a constant oxygen-concentration, a first concentration profile of the first material, and a second concentration profile of the second material. The first material, described and referenced to herein, has a first refractive index about 2.0 or greater and the second material has a second refractive index less than 2.0.

### CROSS-REFERENCE TO RELATED APPLICATIONS

This application claims the benefit of U.S. Provisional Patent Application No. 63/055,160, filed on Jul. 22, 2020, the contents of which are herein incorporated by reference.

### BACKGROUND

### Field

Embodiments of the present disclosure relate to optical device films and methods of forming optical device films.

### Description of the Related Art

Optical devices, such as waveguides, flat optical devices, metasurfaces, color-filters, and anti-reflective coatings, are engineered to exhibit a high refractive index and low absorption loss properties. Metal oxide containing materials, e.g., titanium dioxide (TiO2) have a high refractive index and low absorption loss that enable efficient, large-scale fabrication of optical devices.

Graded-index optical device films are used to control light interacting at the surface or within the film. In conventional optical device films, it is difficult to realize continuous tunability of index over a large range by changing deposition conditions for a single material, and using multiple materials necessitates approximating a continuous profile with a stepped profile.

Conventional optical device films typically include multiple, distinct layers of materials that possess different refractive index properties, such as a step-index waveguide. For example, an optical film is formed with a TiO₂ layer deposited on a surface of the optical device substrate and a silicon dioxide (SiO₂) layer is formed above the TiO₂ layer, where the TiO₂ layer has an index of refraction of about 2.4 (n=2.4) and the SiO₂ layer has an index of refraction of about 1.5 (n=1.5). The difference between the indices of refraction of the TiO₂ layer and the SiO₂ layer is approximately 0.9, which represents a sudden shift for light passing between the layers. This sudden shift may be characterized as a non-continuous step between optical materials, which diminishes the desired optical device properties, such as light reflectivity and light transmissivity, for light passing between the distinct layers. Conventional optical device films often include multiple, distinct layers of more than two materials to reduce the shift of refractive indices between the layers, and thus improve the desired optical properties between layers. However, the refractive indices for these conventional optical device films are non-continuous and optical aberrations may exist in such conventional optical device films.

Accordingly, what is needed in the art are improved optical device films and methods of forming optical device films.

### SUMMARY

In one embodiment, an optical device film is provided. The optical device film includes a thickness divided into a range of zones from a first surface corresponding to 0% of the thickness to a second surface corresponding to 100% of the thickness. Each zone of the range of zones has a zone thickness. The optical device film has an oxygen concentration or a nitrogen concentration in each zone of the range of zones. The optical device film also includes a first material having a first refractive index of about 2.0 or greater and a second material having a second refractive index of less than 2.0. The first material has a first concentration profile throughout the range of zones. The second material has a second concentration profile throughout the range of zones. The second concentration profile is different from the first concentration profile.

In another embodiment, a method is provided. The method includes disposing an optical device substrate on a substrate support. The substrate support is disposed in a chamber. The chamber includes a first target and a second target disposed in the chamber. The first target includes a first material and a second target includes a second material. An optical device film on the optical device substrate is deposited by depositing the first material with a first concentration profile and depositing the second material with a second concentration profile. The depositing the first material includes providing a first power level to the first target. The first concentration profile of the first material is controlled by at least one of increasing or decreasing the first power level provided to the first target. The depositing the second material includes providing a second power level to the second target. The second concentration profile of the second material is controlled by at least one of increasing or decreasing the second power level provided to the second target.

In another embodiment, a method is provided. The method includes disposing an optical device substrate on a substrate support. The substrate support is disposed in a chamber. The chamber includes a first target and a gas source. The first target includes a first material. The gas source is operable to flow a precursor gas comprising a second material. An optical device film on the optical device substrate is deposited by depositing the first material with a first concentration profile and depositing the second material with a second concentration profile. The depositing the first material includes providing a first power level to the first target. The first concentration profile of the first material is controlled by at least one of increasing or decreasing the first power level provided to the first target. The depositing the second material includes providing a precursor gas at a flow rate. The second concentration profile of the second material is controlled by at least one of increasing or decreasing a flow rate of the precursor.

In yet another embodiment, a method is provided. The method includes disposing an optical device substrate in a chamber, flowing a first gas comprising a first material into the chamber at a first flow rate, and flowing a second gas comprising a second material into the chamber at a second flow rate. A first concentration profile of the first material of a deposited optical device film is controlled by at least one of increasing or decreasing the first flow rate during the flowing of the first gas. A second concentration profile of the second material of the deposited optical device film is controlled by at least one of increasing or decreasing the second flow rate during the flowing of the second gas.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic, cross-sectional view of an optical device film according to embodiments described herein.

FIG. 2A and FIG. 2B are schematic, cross-sectional views of optical devices formed from the optical device film.

FIG. 3 is a schematic, cross-sectional view of a physical vapor deposition (PVD) chamber according to embodiments described herein.

FIG. 4 is a schematic, cross-sectional view of a chemical vapor deposition (CVD) chamber according to embodiments described herein.

FIGS. 5-7 are flow diagrams of methods for fabricating an optical device film according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to optical device films and methods of forming optical device films. Specifically, embodiments described herein provide for an optical device film having an oxygen-concentration or nitrogen-concentration, a first concentration profile of a first material, and a second concentration profile of a second material. The optical device film includes the first material at a first concentration and the second material at a second concentration throughout the thickness of the film. The first material, described and referenced to herein, has a first refractive index of about 2.0 or greater. The second material, described and referenced to herein, has a second refractive index of less than 2.0. The first material includes, but is not limited to, oxides or nitrides of titanium (Ti), tantalum (Ta), zirconium (Zr), indium (In), or niobium (Nb). The second material includes, but is not limited to, oxides or nitrides of silicon (Si), aluminum (Al), hafnium (Hf), scandium (Sc), Tin (Sn), yttrium (Y), praseodymium (Pr), or magnesium (Mg).

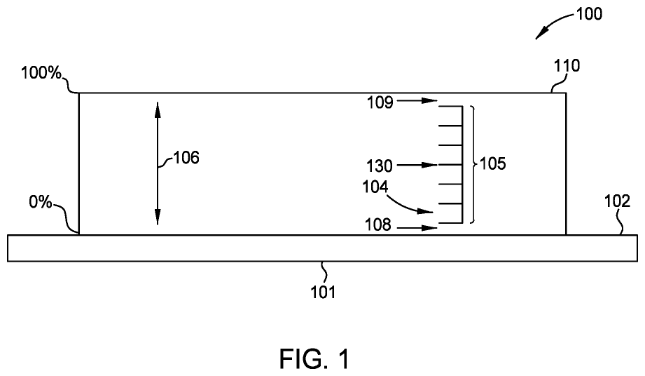

FIG. 1 is a schematic, cross-sectional view of an optical device film 100. The optical device film 100 is disposed on an optical device substrate 101 according to embodiments described herein. The optical device substrate 101 is any suitable optical device substrate on which an optical device may be formed. In one embodiment, the optical device substrate 101 is a silicon (Si) containing optical device substrate. In one embodiment, the optical device substrate 101 is a silicon oxide-based glass or a metal oxide-based glass. In one embodiment, the optical device substrate 101 includes, but is not limited to, silicon (Si), silicon nitride (SiN), silicon dioxide (SiO₂), fused silica, quartz, silicon carbide (SiC), germanium (Ge), silicon germanium (SiGe), indium phosphide (InP), gallium arsenide (GaAs), gallium oxide (GaO), diamond, lithium niobate (LiNbO₃), gallium nitride (GaN), sapphire, tantalum oxide (Ta₂O₅), titanium dioxide (TiO₂) or combinations thereof. The optical device substrate 102 may include a perovskite material that is optically transparent. In another embodiment, the optical device substrate 101 is a layered optical device substrate, for example a thin glass bonded to a silicon carrier. The layered optical device substrate may be a substrate with optical device stacks disposed on the substrate (e.g., patterned optical device films for gratings, waveguides, optoelectronics, monolithically-integrated CMOS-photonic device, heterogeneously-integrated CMOS-photonic devices). In yet another embodiment, the optical device substrate 101 is a laminated substrate comprising multiple layers of bonded glass.

The optical device film 100 has a first surface 102, a second surface 110, and a thickness 106. The thickness 106 of the optical device film 100 is divided into a range of zones 105 measured from the first surface 102 corresponding to 0% of the thickness 106 to the second surface 110 corresponding to 100% of the thickness 106. In one embodiment, which can be combined with other embodiments described herein, the thickness 106 has a constant or substantially constant oxygen or nitrogen concentration throughout the range of zones 105 of the optical device film 100. In one embodiment, the difference in oxygen or nitrogen concentration between each zone 104 of range of zones 105 is an atomic percentage of 10% (e.g., plus or minus 5%). In one embodiment, the oxygen concentration of an optical device film 100 of a first material of TiO₂ and a second material of SiO₂ is about 66.67 atomic percent at plus or minus 10%. Each zone 104 has a zone thickness of about 0.001% to about 50% of the thickness 106. Each zone 104 includes a first material at a first concentration and a second material at a second concentration. The first material, described and referenced to herein, has a first refractive index of about 2.0 or greater. The second material, described and referenced to herein, has a second refractive index of less than 2.0. The first material and the second material may be a metal-containing or a semiconductor material. For example, the first material includes, but is not limited to, oxides or nitrides of titanium (Ti), tantalum (Ta), zirconium (Zr), indium (In), or niobium (Nb). For example, the second material includes, but is not limited to, oxides or nitrides of silicon (Si), aluminum (Al), hafnium (Hf), scandium (Sc), Tin (Sn), yttrium (Y), praseodymium (Pr), or magnesium (Mg).

Introducing the first material and the second material at different concentrations continuously during deposition will allow for the modification of the optical properties i.e., the refractive index, of the optical device film 100. In one embodiment, each zone 104 has a zone thickness of about 0.001% to about 50% of the thickness 106. The first concentration of the first material through the range of zones 105 of the thickness 106 has a first concentration profile, and the second concentration of the second material through the range of zones 105 of the thickness 106 has a second concentration profile. In one embodiment, the first concentration has a maximum concentration at an initial zone 108 of the range of zones 105 adjacent to the first surface 102 and a minimum concentration at a final zone 109 of the range of zones 105 adjacent to the second surface 110. The second concentration has the minimum concentration at the initial zone 108 and a maximum concentration at the final zone 109 of the range of zones 105. In the embodiments where the oxygen concentration is about 66.67 atomic percent at plus or minus 10% (e.g., of a first material of TiO₂ and a second material of SiO₂), the minimum concentration is about 0 atomic percent and the maximum concentration is about 33.3 atomic percent. In the embodiment, the first concentration of each zone 104 deposited immediately over a prior zone is not greater than the first concentration of the prior zone, and the second concentration of each zone 104 deposited immediately over a prior zone is not less than the second concentration of the prior zone.

In another embodiment, the first concentration has the minimum concentration at the initial zone 108 and a maximum concentration at the final zone 109. The second concentration has the maximum concentration at the initial zone 108 and the minimum concentration at the final zone 109. In the embodiment, the first concentration of each zone 104 deposited immediately over a prior zone is not less than the first concentration of the prior zone, and the second concentration of each zone 104 deposited immediately over a prior zone is not greater than the second concentration of the prior zone.

In another embodiment, the first concentration profile and the second concentration profile have sinusoidal profiles. In one embodiment with the first concentration profile and the second concentration profile having sinusoidal profiles, the first concentration has the maximum concentration at the initial zone 108 that decreases to the minimum concentration at a midpoint of the range of zones 105 and that increases to the maximum concentration at the final zone 109. The second concentration has the minimum concentration at the initial zone 108 that increases to the maximum concentration at a midpoint of the range of zones 105 and that decreases to the minimum concentration at the final zone 109. In another embodiment with the first concentration profile and the second concentration profile having sinusoidal profiles, the first concentration has the minimum concentration at the initial zone 108 that increases to the maximum concentration at a midpoint of the range of zones 105 and that decreases to the minimum concentration at the final zone 109. The second concentration has the maximum concentration at the initial zone 108 that decreases to the minimum concentration at a midpoint of the range of zones 105 and that increases to the maximum concentration at the final zone 109.

In yet another embodiment, the first concentration profile of the first material and the second concentration profile of the second material of the optical device film 100 are controlled by the embodiments of the method 500, 600, 700 such that any profile may be obtained. In embodiments of the method 500 of forming the optical device film 100 described herein, the first concentration and second concentration may be controlled by at least one of increasing or decreasing a first power level provided to a first target of the first material or increasing or decreasing a second power level provided to a second target of the second material. In embodiments of the method 600 of forming the optical device film 100 described herein, the first concentration and second concentration may be controlled by at least one of increasing or decreasing a first power level provided to a first target of the first material and increasing or decreasing a flow rate of a precursor gas including the second material. In embodiments of the method 700 of forming the optical device film 100 described herein, the first concentration and second concentration may be controlled by at least one of increasing or decreasing a first flow rate of a first gas including the first material and increasing or decreasing a second flow rate of a second gas including the second material. Therefore, the optical device film 100 having the concentration of oxygen or nitrogen may include any desired profile of the first material and the second material.

The optical device film 100 of the methods 500, 600, 700 described herein formed from the first material and the second material may include one or more of oxides or nitrides of titanium (Ti), tantalum (Ta), zirconium (Zr), indium (In), or niobium (Nb), and one or more of oxides or nitrides of silicon (Si), aluminum (Al), hafnium (Hf), scandium (Sc), Tin (Sn), yttrium (Y), praseodymium (Pr), or magnesium (Mg).

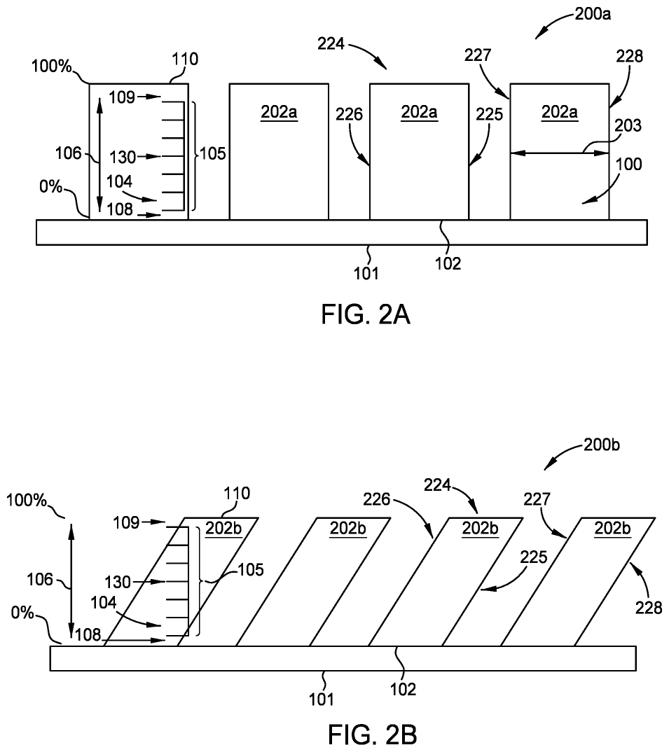

FIG. 2A and FIG. 2B are schematic, cross-sectional views of optical devices 200a, 200b formed from the optical device film 100. The optical devices 200a, 200b include optical device structures 202a, 202b disposed on the optical device substrate 101. The optical device structures 202a, 202b include sub-micron critical dimensions, e.g., nanosized dimensions, corresponding to the widths 203 of the optical device structures 202a, 202b. The optical device structures 202a may be binary structures with top surface 224 of the optical device structures 202a parallel to the surface 102 of the optical device substrate 101. A first sidewall 225 and a second sidewall 226 are parallel to a third sidewall 227 and a fourth sidewall 228. The sidewalls 225, 226, 227, and 228 are oriented normal to a major axis of the optical device substrate 101. The optical device structures 202b may be angled structures with the sidewalls 225, 226, 227, and 228 slanted relative to the surface 102 of the optical device substrate 101. The optical devices 200a, 200b are formed form the optical device film 100 having the first concentration profile of the first material, the second concentration profile of the second material, and a concentration of oxygen or nitrogen throughout the thickness 106 of the optical device film 100.

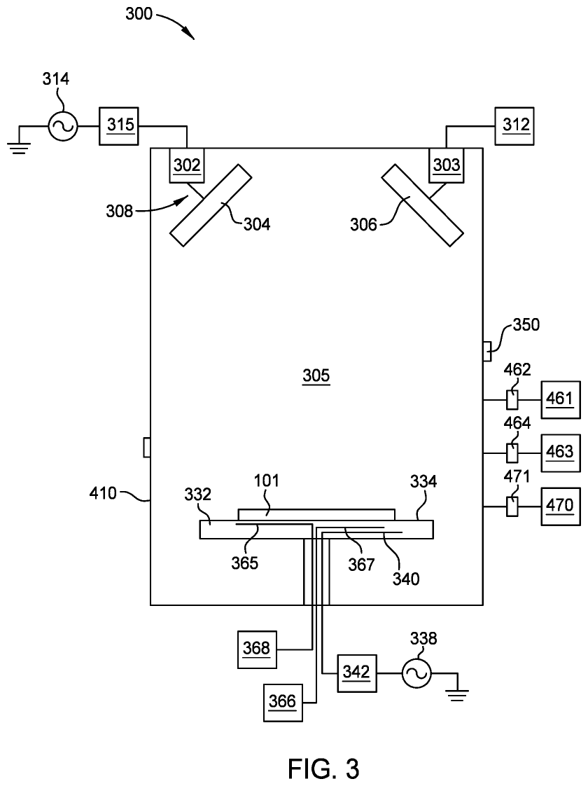

FIG. 3 is a schematic, cross-sectional view of a PVD chamber 300. The PVD chamber 300 may be used for the methods 500 and 600 described herein. It is to be understood that the PVD chamber 300 described below is an exemplary PVD chamber and other PVD chambers, including PVD chambers from other manufacturers, may be used with or modified to accomplish aspects of the present disclosure.

The PVD chamber 300 includes a plurality of cathodes 302, 303 having a corresponding plurality of targets (at least one first target 304 and at least one second target 306), attached to the chamber body 310 (e.g., via a chamber body adapter 308). The first target 304 includes at least one first material described herein and the second target 306 includes at least one second material described herein. Each cathode (e.g., the first target 304 and second target 306) may be coupled to a DC power source 312 or an RF power source 314 and matching network 316.

The PVD chamber 300 is configured to include a substrate support 332 having a support surface 334 to support the optical device substrate 101. The PVD chamber 300 includes an opening 350 (e.g., a slit valve) through which an end effector (not shown) extends to place an optical device substrate 101 onto lift pins (not shown) for lowering the optical device substrate 101 onto a support surface 334.

The PVD chamber 300 includes a sputter gas source 361 operable to supply a sputter gas, such as argon (Ar) to a process volume 305. A gas flow controller 362 is disposed between the sputter gas source 361 and the process volume 305 to control a flow of the sputter gas from the sputter gas source 361 to the process volume 305. The PVD chamber 300 includes a reactive gas source 363 operable to supply a reactive gas, such as an oxygen-containing gas or nitrogen-containing gas to the process volume 305. A gas flow controller 364 is disposed between the reactive gas source 363 and the process volume 305 to control a flow of the reactive gas from the reactive gas source 363 to the process volume 305. The PVD chamber 300 may include a precursor gas source 370 operable to supply a precursor gas to the process volume 305. A gas flow controller 371 is disposed between the precursor gas source 370 and the process volume 305 to control a flow of the precursor gas from the precursor gas source 370 to the process volume 305.

In the embodiment shown in FIG. 3, the substrate support 332 includes an RF bias power source 338 coupled to a bias electrode 340 disposed in the substrate support 332 via a matching network 342. The substrate support 332 includes a mechanism (not shown) that retains the optical device substrate 101 on a support surface 334 of the substrate support 332, such as an electrostatic chuck, a vacuum chuck, a substrate retaining clamp, or the like. The substrate support 332 includes a cooling conduit 365 disposed in the substrate support 332 where the cooling conduit 365 controllably cools the substrate support 332 and the optical device substrate 101 positioned thereon to a predetermined temperature, for example between about −20° C. to 300° C. The cooling conduit 365 is coupled to a cooling fluid source 368 to provide cooling fluid (not shown). The substrate support 332 also includes a heater 367 embedded therein. The heater 367, such as a resistive element, disposed in the substrate support 332 is coupled to an optional heater power source 366 and controllably heats the substrate support 332 and the optical device substrate 101 positioned thereon to a predetermined temperature, for example between about −20° C. to 300° C.

While FIG. 3 depicts one first target 304 and one second target 306, the PVD chamber 300 may include one or more first targets 304 and/or one or more second targets 306. For example, 3-5 targets selected from at least one of the first targets 304 or the second targets 306 may be included in the PVD chamber 300. Each first target 304 is operable to deposit a different material. For example, 3-5 second targets 306 may be included in the PVD chamber. Each optical device material target 306 is operable to deposit a different material. In embodiments with the one or more first targets 304 and the one or more second 306, each first target 304 is operable to deposit a different first material and/or each second target 306 is operable to deposit a different second material.

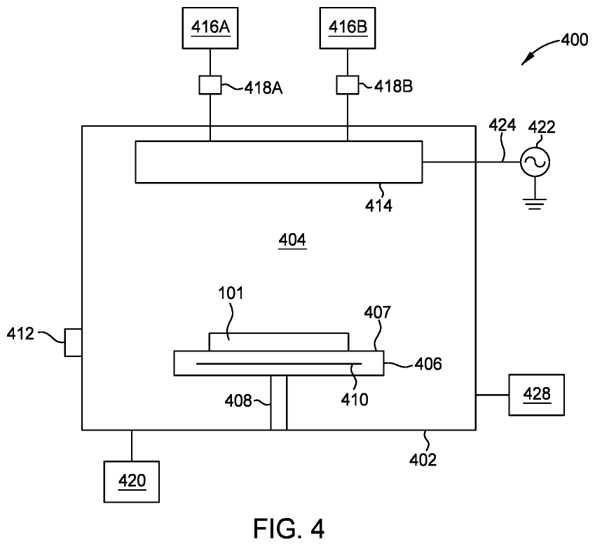

FIG. 4 is a schematic, cross-sectional view of a CVD chamber 400 that may be used for the method 700 described herein. It is to be understood that the CVD chamber 400 described herein is an exemplary CVD chamber and other CVD chambers, including CVD chambers from other manufacturers, may be used with or modified to accomplish aspects of the present disclosure.

The CVD chamber 400 has a chamber body 402 that includes a processing volume 404 having a substrate support 406 disposed therein to support an optical device substrate 101 thereon. The substrate support 406 includes a heating/cooling conduit 410 and a mechanism that retains the optical device substrate 101 on a support surface 407 of the substrate support 406, such as an electrostatic chuck, a vacuum chuck, a substrate retaining clamp, or the like. The substrate support 406 is coupled to and movably disposed in the processing volume 404 by a stem 408 connected to a lift system (not shown) that moves the substrate support 406 between an elevated processing position and a lowered position that facilitates transfer of the optical device substrate 101 to and from the CVD chamber 400 through an opening 412.

The CVD chamber 400 includes a flow controller 418A disposed between a first gas source 416A and a chamber body 402 to control the first flow rate of the first process gas of the first material from the first gas source 416A to a showerhead 414. The CVD chamber 400 includes a flow controller 418B disposed between a second gas source 416B and the chamber body 402 to control the second flow rate of the second process gas of the second material from the second gas source 416B to a showerhead 414. The showerhead 414 is connected to an RF power source 422 by an RF feed 424 for generating a plasma in the processing volume 404 from the first process gas and/or second process gas. The RF power source 422 provides RF energy to the showerhead 414 to facilitate generation of a plasma between the showerhead 414 and the substrate support 406. A vacuum pump 420 is coupled to the chamber body 402 for controlling the pressure within the processing volume 404. A controller 428 is coupled to the CVD chamber 400 and configured to control aspects of the CVD chamber 400 during processing.

While FIG. 4 depicts a first gas source 416A and a second gas source 416B, the CVD chamber 400 may include one or more first gas sources 416A and/or one or more second gas sources 416B. For example, 3-5 gas sources selected from at least one of the first gas sources 416A or the second gas sources 416B may be included in the CVD chamber 400. In embodiments with the one or more first gas sources 416A and the one or more second gas sources 416B, each first gas source 416A is operable to deposit a different first material and/or each second gas source 416B is operable to deposit a different second material.

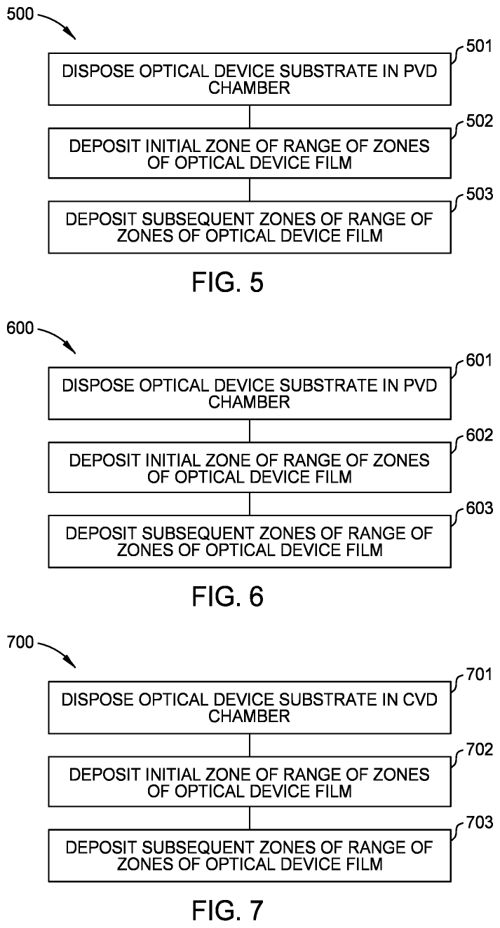

FIG. 5 is a flow diagram of a method 500 of forming an optical device film 100. The optical device film 100 may be utilized in subsequent processes to form the devices 200a, 200b. To facilitate explanation, FIG. 5 will be described with reference to the PVD chamber 300 of FIG. 3. However, it is to be noted that a PVD chamber other than the PVD chamber 300 of FIG. 3 may be utilized in conjunction with method 500.

At operation 501, the optical device substrate 101 is disposed on a substrate support in the PVD chamber 300. At operation 502, an initial zone 108 of the range of zones 105 of the optical device film 100 is deposited. The first target 304 having the first material is set to a first power level and the second target 306 having the second material is set to a second power level. In one embodiment, the first material of the first target 304 and/or the second material of the second target 306 includes an oxygen-containing material or a nitrogen-containing material. The first material, described and referenced to herein, has a first refractive index about 2.0 or greater. The second material, described and referenced to herein, has a second refractive index less than 2.0. The first material includes, but is not limited to, oxides or nitrides of titanium (Ti), tantalum (Ta), zirconium (Zr), indium (In), or niobium (Nb). The second material includes, but is not limited to, oxides or nitrides of silicon (Si), aluminum (Al), hafnium (Hf), scandium (Sc), Tin (Sn), yttrium (Y), praseodymium (Pr), or magnesium (Mg). In another embodiment, an oxygen-containing gas or a nitrogen-containing gas is supplied to the process volume 305. In the embodiment, the deposited first material and the second material react with the oxygen-containing gas or nitrogen-containing gas to form the initial zone 108 of the optical device film 100. In another embodiment, the optical device substrate 101 is maintained at a predetermined temperature between −20° C. to 300° C.

In one embodiment, a first concentration of the first material has a maximum concentration in the initial zone 108 of the range of zones 105 by applying the first power level at the upper limit of the first power level to the first target 304. The upper limit of the first power level corresponding to the highest power level is supplied to the first target 304 during the method 500. In the embodiment, a second concentration of the second material has the minimum concentration at the initial zone 108 not applying the second power level or applying the second power level at the lower limit of the second power level to the second target 306. The lower limit of the second power level corresponding to the lowest power level is supplied to the second target 306 during the method 500. In another embodiment, the first concentration of the first material has a minimum concentration in the initial zone 108 of the range of zones 105 by not applying the first power level or applying the first power level at the lower limit of the first power level to the first target 304. The lower limit of the first power level corresponding to the lowest power level is supplied to the first target 304 during the method 500. In the embodiment, the second concentration of the second material has the maximum concentration at the initial zone 108 by applying the second power level at the upper limit of the second power level to the second target 306. The upper limit of the second power level corresponding to the highest power level is supplied to the second target 306 during the method 500. In yet another embodiment, the first concentration and second concentration may be controlled by at least one of setting the first power level provided to the first target 304 of the first material and setting a second power provided to the second target 306 of the second material at different power levels between the upper limit and lower limit of the first and second power levels.

At operation 503, subsequent zones of the optical device film 100 are deposited until the final zone 109 of the range of zones 105 is deposited. The deposition of the subsequent zones includes at least one of setting the first power level provided to the first target 304 of the first material and setting a second power level provided to the second target 306 of the second material at different power levels to form the optical device film 100. The optical device film 100 includes an oxygen concentration or nitrogen concentration, the first concentration profile of the first material, and the second concentration profile of the second material. In one embodiment, which can be combined with other embodiments described herein, the thickness 106 has a constant or substantially constant oxygen or nitrogen concentration throughout the range of zones 105 of the optical device film 100.

FIG. 6 is a flow diagram of a method 600 of forming an optical device film 100. The optical device film 100 may be utilized in subsequent processes to form the devices 200a, 200b. To facilitate explanation, FIG. 6 will be described with reference to the PVD chamber 300 of FIG. 3. However, it is to be noted that a PVD chamber other than the PVD chamber 300 of FIG. 3 may be utilized in conjunction with method 600.

At operation 601, the optical device substrate 101 is disposed on a substrate support in the PVD chamber 300. At operation 602, an initial zone 108 of the range of zones 105 of the optical device substrate 101 is deposited. The first target 304 having the first material is set to a first power level and the precursor gas including the second material is provided at a precursor flow rate. In one embodiment, the first material of the first target 304 and/or the precursor gas of the second material includes an oxygen-containing material or a nitrogen-containing material. The first material, described and referenced to herein, has a first refractive index about 2.0 or greater. The second material, described and referenced to herein, has a second refractive index less than 2.0. The first material includes, but is not limited to, oxides or nitrides of titanium (Ti), tantalum (Ta), zirconium (Zr), indium (In), or niobium (Nb). The second material includes, but is not limited to, oxides or nitrides of silicon (Si), aluminum (Al), hafnium (Hf), scandium (Sc), Tin (Sn), yttrium (Y), praseodymium (Pr), or magnesium (Mg). In another embodiment, an oxygen-containing gas is supplied to the process volume 305. In another embodiment, an oxygen-containing gas or a nitrogen-containing gas is supplied to the process volume 305. In the embodiment, the deposited first material and the second material react with the oxygen-containing gas or the nitrogen-containing gas to form the initial zone 108 of the optical device film 100. In another embodiment, the optical device substrate 101 is maintained at a predetermined temperature between about −20° C. to 300° C.

In one embodiment, a first concentration of the first material has a maximum concentration in the initial zone 108 of the range of zones 105 by applying the first power level at the upper limit of the first power level to the first target 304. The upper limit of the first power level corresponding to the highest power level is supplied to the first target 304 during the method 600. In the embodiment, a second concentration of the second material has the minimum concentration at the initial zone 108 by not flowing the precursor gas or flowing the precursor gas at the lowest flow rate during the method 600. In another embodiment, the first concentration of the first material has a minimum concentration in the initial zone 108 of the range of zones 105 by not applying the first power level or applying the first power level at the lower limit of the first power level to the first target 304. The lower limit of the first power level corresponding to the lowest power level is supplied to the first target 304 during the method 600. In the embodiment, the second concentration of the second material has the maximum concentration at the initial zone 108 by flowing the precursor gas at the highest flow rate during the method 600 during the method 500. In yet another embodiment, the first concentration and second concentration may be controlled by at least one of varying the first power level provided to the first target 304 of the first material and varying the flow rate of precursor gas during the method 600.

At operation 603, subsequent zones of the optical device film 100 are deposited until the final zone 109 of the range of zones 105 is deposited. The deposition of the subsequent zones includes at least one of increasing or decreasing a first power level provided to a first target of the first material and increasing or decreasing a flow rate of a precursor gas including the second material to form the optical device film 100 having an oxygen concentration or nitrogen concentration, the first concentration profile of the first material, and the second concentration profile of the second material. In one embodiment, which can be combined with other embodiments described herein, the thickness 106 has a constant or substantially constant oxygen or nitrogen concentration throughout the range of zones 105 of the optical device film 100.

FIG. 7 is a flow diagram of a method 700 of forming an optical device film 100. The optical device film 100 may be utilized in subsequent processes to form the devices 200a, 200b. To facilitate explanation, FIG. 7 will be described with reference to the CVD chamber 400 of FIG. 4. However, it is to be noted that a CVD chamber other than the CVD chamber 400 of FIG. 4 may be utilized in conjunction with method 700.

At operation 701, the optical device substrate 101 is disposed on a substrate support in the CVD chamber 400. At operation 702, an initial zone 108 of the range of zones 105 of the optical device substrate 101 is deposited. The first gas has a first gas flow rate and the second gas has a second gas flow rate. The first material of the first gas, described and referenced to herein, has a first refractive index about 2.0 or greater. The second material of the second gas, described and referenced to herein, has a second refractive index less than 2.0. In one embodiment, the first material of the first target 304 and/or the precursor gas of the second material includes an oxygen-containing material or a nitrogen-containing material. In one embodiment, the optical device substrate 101 is maintained at a predetermined temperature between about −20° C. to 300° C.

In one embodiment, a first concentration of the first material has a maximum concentration in the initial zone 108 of the range of zones 105 by flowing the first gas at the highest flow rate during the method 700. In the embodiment, a second concentration of the second material has the minimum concentration at the initial zone 108 by not flowing the second gas or flowing the second gas at the lowest flow rate during the method 700. In another embodiment, the first concentration of the first material has a minimum concentration in the initial zone 108 of the range of zones 105 by not flowing the first gas or flowing the first gas at the lowest flow rate during the method 700. In the embodiment, the second concentration of the second material has the maximum concentration at the initial zone 108 by flowing the second gas at the highest flow rate during the method 700. In yet another embodiment, the first concentration and second concentration may be controlled by at least one of varying the first gas flow rate and varying the second gas flow rate during the method 700.

At operation 703, subsequent zones of the optical device film 100 are deposited until the final zone 109 of the range of zones 105 is deposited. The deposition of the subsequent zones includes at least one of increasing or decreasing a first flow rate of a first gas including the first material and increasing or decreasing a second flow rate of a second gas including the second material to form the optical device film 100 having a oxygen concentration or a nitrogen concentration, the first concentration profile of the first material, and the second concentration profile of the second material. In one embodiment, which can be combined with other embodiments described herein, the thickness 106 has a constant or substantially constant oxygen or nitrogen concentration throughout the range of zones 105 of the optical device film 100.

In summation, optical device films and methods of forming optical device films having an oxygen-concentration or a nitrogen concentration, the first concentration profile of the first material, and the second concentration profile of the second material are described herein. Introducing the first material and the second material at different concentrations continuously during deposition will allow for the modification of the optical properties i.e., the refractive index, of the optical device film. In one embodiment, a method includes controlling the first concentration profile and the second concentration profile by at least one of increasing or decreasing a first power level provided to a first target of the first material or increasing or decreasing a second power provided to a second target of the second material. In another embodiment, a method includes controlling the first concentration profile and the second concentration profile by at least one of increasing or decreasing a first power level provided to a first target of the first material and increasing or decreasing a flow rate of a precursor gas including the second material. In yet another embodiment, a method includes controlling the first concentration profile and the second concentration profile by at least one of increasing or decreasing a first flow rate of a first gas including the first material and increasing or decreasing a second flow rate of a second gas including the second material.

While the foregoing is directed to examples of the present disclosure, other and further examples of the disclosure may be devised without departing from the basic scope thereof, and the scope thereof is determined by the claims that follow.

What is claimed is:

1. An optical device film, comprising:
a thickness divided into a range of zones from a first surface substantially corresponding to 0% of the thickness to a second surface substantially corresponding to 100% of the thickness, each zone of the range of zones having a zone thickness;
an oxygen concentration or a nitrogen concentration in each zone of the range of zones of the optical device film;
a first material having a first refractive index of about 2.0 or greater, the first material having a first concentration profile throughout the range of zones; and
a second material having a second refractive index of less than 2.0, the second material having a second concentration profile throughout the range of zones, the second concentration profile different from the first concentration profile.

2. The optical device film of claim 1, wherein the zone thickness is about 0.001% to about 50% of the thickness.

3. The optical device film of claim 1, wherein the first material includes oxides or nitrides of titanium (Ti), tantalum (Ta), zirconium (Zr), indium (In), or niobium (Nb).

4. The optical device film of claim 1, wherein the second material includes oxides or nitrides of silicon (Si), aluminum (Al), hafnium (Hf), scandium (Sc), Tin (Sn), yttrium (Y), praseodymium (Pr), or magnesium (Mg).

5. The optical device film of claim 1, wherein the oxygen concentration is about 66.67 atomic percent at plus or minus 10%.

6. The optical device film of claim 1, wherein:
an initial zone of the range of zones adjacent to the first surface, comprises:
a maximum concentration of the first material; and
a minimum concentration of 0 atomic percent of the second material; and
a final zone of the range of zones adjacent to the second surface, comprises:
a minimum concentration of 0 atomic percent of the first material; and
a maximum concentration of the second material.

7. The optical device film of claim 6, wherein:
the first concentration profile has a first concentration of each zone disposed immediately over a prior zone not greater than the first concentration of the prior zone; and
the second concentration profile has a second concentration of each zone disposed immediately over the prior zone not less than the second concentration of the prior zone.

8. The optical device film of claim 6, wherein:
the first concentration profile has the maximum concentration at the initial zone of the range of zones, the first concentration profile has the minimum concentration at a midpoint of the range of zones, the first concentration profile has the maximum concentration at the final zone of the range of zones; and
the second concentration profile has the minimum concentration at the initial zone of the range of zones, the second concentration profile has the maximum concentration at the midpoint of the range of zones, the second concentration profile has the minimum concentration at the final zone of the range of zones.

9. The optical device film of claim 1, wherein:
an initial zone of the range of zones adjacent to the first surface, comprises:
a maximum concentration of the second material; and
a minimum concentration of 0 atomic percent of the first material; and
a finial zone of the range of zones adjacent to the second surface, comprises:
a minimum concentration of 0 atomic percent of the second material; and
a maximum concentration of the first material.

10. The optical device film of claim 9, wherein:
the first concentration profile has a first concentration of each zone disposed immediately over a prior zone not less than the first concentration of the prior zone; and
the second concentration profile has a second concentration of each zone disposed immediately over the prior zone not greater than the second concentration of the prior zone.

11. The optical device film of claim 9, wherein:
the first concentration profile has the minimum concentration at the initial zone of the range of zones, the first concentration profile has the maximum concentration at a midpoint of the range of zones, the first concentration profile has the minimum concentration at the final zone of the range of zones; and
the second concentration profile has the maximum concentration at the initial zone of the range of zones, the second concentration profile has the minimum concentration at the midpoint of the range of zones, the second concentration profile has the maximum concentration at the final zone of the range of zones.

12. The optical device film of claim 1, wherein the optical device film comprises a plurality of optical device structures disposed therein.

13. The optical device film of claim 12, wherein the plurality of optical device structures are slanted relative to the first surface of the optical device film.

14. The optical device film of claim 12, wherein the difference in the oxygen or the nitrogen concentration between each zone of the range of zones is an atomic percentage of 10%.

15. A method, comprising:
disposing an optical device substrate on a substrate support, the substrate support disposed in a chamber, the chamber comprising:
a first target disposed in the chamber, the first target comprising a first material; and
a second target disposed in the chamber, the second target comprising a second material; and
depositing an optical device film on the optical device substrate, comprising:
depositing the first material with a first concentration profile, the depositing the first material comprising providing a first power level to the first target, wherein the first concentration profile of the first material is controlled by at least one of increasing or decreasing the first power level provided to the first target; and
depositing the second material with a second concentration profile, the depositing the second material comprising providing a second power level to the second target, wherein the second concentration profile of the second material is controlled by at least one of increasing or decreasing the second power level provided to the second target.

16. The method of claim 15, wherein the first material includes oxides or nitrides of titanium (Ti), tantalum (Ta), zirconium (Zr), indium (In), or niobium (Nb).

17. The method of claim 15, wherein the second material includes oxides or nitrides of silicon (Si), aluminum (Al), hafnium (Hf), scandium (Sc), Tin (Sn), yttrium (Y), praseodymium (Pr), or magnesium (Mg).

18. A method, comprising:
disposing an optical device substrate on a substrate support, the substrate support disposed in a chamber, the chamber comprising:
a first target disposed in the chamber, the first target comprising a first material; and
a gas source operable to flow a precursor gas comprising a second material; and
depositing an optical device film on the optical device substrate, comprising:
depositing the first material with a first concentration profile, the depositing the first material comprising providing a first power level to the first target, wherein the first concentration profile of the first material is controlled by at least one of increasing or decreasing the first power level provided to the first target; and
depositing the second material with a second concentration profile, the depositing the second material comprising providing a precursor gas at a flow rate, wherein the second concentration profile of the second material is controlled by at least one of increasing or decreasing a flow rate of the precursor gas.

19. The method of claim 18, wherein the second material includes oxides or nitrides of silicon (Si), aluminum (Al), hafnium (Hf), scandium (Sc), Tin (Sn), yttrium (Y), praseodymium (Pr), or magnesium (Mg).

20. A method, comprising:
disposing an optical device substrate in a chamber;
flowing a first gas comprising a first material into the chamber at a first flow rate, wherein a first concentration profile of the first material of a deposited optical device film is controlled by at least one of increasing or decreasing the first flow rate during the flowing of the first gas; and
flowing a second gas comprising a second material into the chamber at a second flow rate, wherein a second concentration profile of the second material of the deposited optical device film is controlled by at least one of increasing or decreasing the second flow rate during the flowing of the second gas.
